(19) United States
(12) Patent Application Publication
(10) Pub. No.: US 2011/0163399 A1
(43) Pub. Date: Jul. 7, 2011

(54) Method for Manufacturing Microelectronic Devices and Devices According to Such Methods

(75) Inventors: Ann Witvrouw, Herent (BE); Luc Haspeslagh, Lubbeek-Linden (BE); Gert Claes, Kessel-lo (BE)

(73) Assignee: IMEC, Leuven (BE)

(21) Appl. No.: 12/955,539

(22) Filed: Nov. 29, 2010

(30) Foreign Application Priority Data
Nov. 30, 2009 (EP) 09177497.6

(51) Int. Cl. H01L 29/84; H01L 21/62

(52) U.S. Cl. 257/419; 438/51; 257/E21.52; 257/E29.324

(57) ABSTRACT

A method is disclosed for manufacturing a sealed cavity in a microelectronic device, comprising forming a sacrificial layer at least at locations where the cavity is to be provided, depositing a membrane layer over the top of the sacrificial layer, patterning the membrane layer in at least two separate membrane layer blocks, removing the sacrificial layer through the membrane layer, and sealing the cavity by sealing the membrane layer, wherein patterning the membrane layer is performed after removal of the sacrificial layer.

### CROSS-REFERENCE TO RELATED APPLICATIONS

The present application claims priority to European Patent Application EP 09177497.6 filed in the European Patent Office on Nov. 30, 2009, the entire contents of which is incorporated herein by reference.

### TECHNICAL FIELD

The present disclosure relates to the field of microelectronics processing. In particular it relates to zero-level or thin film packaging technology for MEMS devices.

### BACKGROUND

MEMS devices often need a sealed cavity, for instance when manufacturing a pressure sensor or when packaging a MEMS device with a thin film cap. Electrical connections to the sealed cavity are provided via bond pads adjacent to the sealed cavity. The cavities can be created by surface micromachining: for instance by removing a sacrificial layer through the etching of holes in a capping layer or membrane layer overlying the sacrificial layer. Next the openings in the membrane layer need to be closed to create the sealed cavity. The closure is done by forming a sealing layer overlying the membrane layer, for instance using a deposited or reflowed layer. After sealing, the sealing layer needs to be removed at the bond pad locations.

The sealing layer removal step requires lithography and etching processes, which are very difficult if the surface on which they are applied comprises large topography variations.

As membranes for thin film packaging are often 10 to 20 micrometer thick, such topography variations can certainly cause problems.

In order to limit such problems, it is recommendable to have a process flow maintaining an almost flat surface, i.e. with a typical maximum of about 1 micrometer of topography variation, up until the last lithography step.

In the paper “Stable Thin Film Encapsulation of Acceleration Sensors Using Polycrystalline Silicon as Sacrificial and Encapsulation Layer,” Sensors and Actuators, Vol 114/2-3 pp 355-361 (2004), A. Hoechst et al., it was proposed to form narrow trenches, i.e. having roughly the same width as the etch holes in the membrane layer, when forming the etch holes in the membrane. The narrow trenches split up the membrane layer into separate membrane blocks, one for each cavity present on the common substrate, and separate also the bond pads from the membrane blocks. The narrow trenches are sealed during the sealing process of the etch holes, while the resulting membrane surface is sufficiently planar for subsequent lithography. This solution however limits the possible membrane shape and may lead to capacitive coupling between the bond pads and the membrane, as the allowed spacing is small. Moreover, the membrane blocks may be short circuited when the sealing layer is conductive, typically resulting in a failing device.

There is a need for alternative encapsulation methods which maintain a substantially flat surface up until the last lithography step, and which solves at least some of the above mentioned problems.

### SUMMARY

According to a first aspect of the present disclosure, a method is disclosed for manufacturing a sealed cavity in a microelectronic device, comprising forming on a substrate a sacrificial layer at least at locations where the cavity is to be provided, depositing a membrane layer on top of the sacrificial layer overlying the substrate, patterning the membrane layer in at least two separate membrane layer blocks whereby at least one membrane block corresponds to the location of a cavity, removing the sacrificial layer through the membrane layer blocks thereby forming the cavity, and thereafter sealing the cavity by sealing the membrane layer blocks wherein the patterning of the membrane layer into at least two separate membrane layer blocks is performed only after removal of the sacrificial layer.

For the purpose of the present disclosure a sacrificial layer is a layer which is intended to be, at least in part, removed before the finalization of the respective semiconductor device. Typically sacrificial layers are layers which can be used to temporarily support structural elements or layers of a semiconductor device.

The membrane is patterned such that the resulting membrane blocks are disconnected, i.e. they are not in physical and/or electrical contact with each other.

By postponing the definition of the membrane layer, by patterning the membrane layer into at least two separate membrane layer blocks, the mechanical strength of the intermediate or final device can be increased.

It should be noted that in typical process sequences of the prior art, the membrane layer is defined simultaneously with the creation of the etch holes in the membrane layer at the location of the cavity, such that portions of the sacrificial layer underlying the membrane layer at locations different from locations where cavities are to be formed, may also be removed. In other words, there is a risk that the sacrificial layer can be removed through the trenches separating the membrane layer blocks. This may weaken the physical strength of the device or parts thereof.

According to preferred embodiments of the first aspect of the present disclosure, patterning the membrane layer in order to define at least two separate membrane layer blocks is performed after sealing of the membrane layer.

By further postponing the definition of the membrane layer until after sealing of the membrane layer, the intermediate topography of the processing surface is strongly reduced, when compared to typical process sequences wherein the definition of the membrane layer is performed contemporaneously with the creation of the etch holes in the membrane. This means that lithography and etching processes for sealing layer removal can be applied more accurately.

According to embodiments of the first aspect of the present disclosure, the method is performed on a substrate which comprises at least one buried metal layer. The substrate can be, for instance, a CMOS wafer.

According to embodiments of the first aspect, a plurality of sealed cavities is produced contemporaneously. The sealed cavities can be formed adjacent to each other, during a process of wafer level processing whereby process steps are applied over substantially the entire surface of the substrate, such as a wafer. The cavities can be substantially equal, similar, or different in shape. Parallel processing of different devices per wafer is thus possible. Such a parallel processing may advantageously comprise the processing of mainly identical devices.

According to embodiments of the first aspect, the method comprises forming a bond pad on the membrane layer, such that an electrical connection is created between the bond pad and the membrane layer at a location adjacent to the cavity.

According to embodiments of the first aspect, patterning the membrane layer comprises forming a cap membrane layer block positioned substantially above the cavity.

According to embodiments of the first aspect, patterning the membrane layer comprises forming a bond pad membrane layer block positioned adjacent to the cavity. In embodiments wherein the bond pad is present, the bond pad membrane layer block can comprise the bond pad. The bond pad membrane layer block is typically positioned adjacent to the cavities at a distance of the cap membrane layer block, when looking at a top view of the patterned membrane layer.

According to embodiments of the first aspect of the present disclosure, the patterning of the membrane layer in at least two separate membrane layer blocks is performed after formation of the bond pad. This allows a more successful formation of the bond pad, as it can be formed on a substantially flat surface. The patterning of the membrane layer in order to define at least two separate membrane layer blocks preferably separates the bond pad from sidewalls of the cavity.

According to embodiments of the first aspect of the present disclosure, the method further comprises manufacturing at least one MEMS device within the cavity and providing an electrical connection for the MEMS device, the electrical connection comprising the buried metal layer. The electrical connection is preferably a connection between the bond pad and the MEMS device. Hereby, the MEMS device is thus connected electrically with the buried metal layer and preferably further with the bond pad.

According to embodiments of the first aspect of the present disclosure, wherein at least one MEMS device is manufactured, the method comprises the formation of a structural MEMS layer, at least a first portion of which is comprised in the MEMS device and at least a second portion of which is comprised in the electrical connection between the MEMS device and the bond pad.

For the purpose of the present disclosure a structural layer is a layer that is intended to be, at least partially, part of a functional microelectronic device.

According to typical embodiments of the present disclosure, removing the sacrificial layer through the membrane layer further comprises patterning the membrane layer at a location substantially above the cavity, in order to provide at least one etch hole for removing at least part of the sacrificial layer below the membrane layer, independently of the patterning process of the membrane layer wherein at least two separate membrane layer blocks are defined. The process can optionally be performed after a planarization process of the deposited membrane layer.

The patterning of the membrane layer, in any of the other embodiments, into at least two separate membrane layer blocks, preferably comprises isolating the bond pad and the bond pad membrane layer block from the cap membrane layer block and the sidewall of the corresponding cavity.

According to a second aspect of the present disclosure, a microelectronic device is disclosed comprising a cavity, a membrane layer above the cavity closing off the cavity, the membrane layer being adapted for allowing the removal of a sacrificial material within the cavity through the membrane layer, wherein the membrane layer is a single piece layer.

In another view the membrane layer is not patterned in order to define at least two separate membrane layer blocks (as for instance a cap membrane layer block and a bond pad membrane layer block). In still another view the membrane layer is an interconnected layer. Viewed otherwise, the membrane layer is such that between any pair of randomly selected points on the surface of the layer a single continuous line can be drawn connecting them.

This aspect of the present disclosure relates to a characteristic intermediate device produced while performing methods according to the first aspect of the present disclosure.

According to embodiments of the second aspect of the present disclosure, the sacrificial material is applied in layers and is thus layered.

According to embodiments of the second aspect of the present disclosure, the microelectronic device further comprises at least one etch hole in the membrane layer above the cavity, said etch hole communicating with the cavity.

According to embodiments of the second aspect of the present disclosure, the microelectronic device comprises at least one sealing layer covering and sealing the membrane layer above said cavity. The at least one sealing layer can be provided on a substantially flat surface, and can thus comprise a substantially flat lower surface.

According to embodiments of the second aspect of the present disclosure, the microelectronic device comprises packaging anchors defining the sidewalls of the cavity, and comprises at least a support structure of sacrificial material at locations outside the cavity, the support structure being formed by a portion of sacrificial material used for temporarily filling the cavity with sacrificial material. The support structure can provide support for the sidewalls of the cavity or for structures outside said cavity.

According to embodiments of the second aspect of the present disclosure, the support structure comprises a substantially flat upper surface at a level which corresponds with the level of the lower surface of the membrane layer. According to preferred embodiments the portion surrounds and joins the packaging anchors or structures outside said cavity.

The structures outside the cavity can be, for instance, electrical connection structures. The electrical connection structures can provide an electrical connection from a location near the front surface of the semiconductor device towards a buried conductor layer, and further towards the MEMS device present in the cavity by means of the buried conductor layer. The electrical connection can comprise a pillar-type structure with one end located near the front surface of said device and the other end abutting on said buried metal layer. The remaining portions of the sacrificial layers can thus be located such that they provide mechanical support for said pillar structures located outside the cavity.

According to embodiments the membrane layer extends over the whole surface of the substrate.

According to a third aspect of the present disclosure, a microelectronic device is disclosed comprising a sealed cavity delimited by a substrate, sidewalls of the cavity, and a cap membrane layer block positioned above the cavity, wherein at least a support structure is present at locations outside the cavity, the support structure being formed by a portion of sacrificial material used for temporarily filling the cavity. This aspect of the present disclosure relates to devices produced by performing methods according to the first aspect of the present disclosure.

The support structure can provide support for the sidewalls of the cavity of for structures outside said cavity.

According to embodiments of the third aspect of the present disclosure, the sacrificial material is applied in layers and is thus layered.

The structures outside the cavity can be the same as those described for aspects of the second aspect of the present disclosure.

According to embodiments of the third aspect of the present disclosure, the substrate comprises at least one buried metal layer, and the cavity comprises a MEMS device, the microelectronic device further comprising a bond pad membrane layer block positioned adjacent to the cavity, the cap membrane layer block and the bond pad membrane layer block being electrically isolated from each other. The cap membrane layer block and the bond pad membrane layer block preferably originate from a same membrane layer.

According to embodiments of the third aspect of the present disclosure, the membrane layer blocks positioned adjacent to the cavities support a bond pad, and the device comprises an electrical connection between the bond pad and the MEMS device, the electrical connection comprising the bond pad membrane block and the buried metal layer.

According to embodiments of the third aspect of the present disclosure, the support structure mechanically supports the electrical connection. For providing support to the electrical connection, the portion of sacrificial material is preferably located adjacent or joining said electrical connection.

According to embodiments of the third aspect of the present disclosure, in any of the other embodiments of the third aspect, the portion of sacrificial material is located adjacent to the electrical connection of the bond pad, at the level of a structural layer forming or comprised in the MEMS device, the electrical connection comprising at least part of the structural layer. Also, the portion of sacrificial material can be located below that level, i.e. between that level and the substrate.

According to embodiments of the third aspect of the present disclosure, the portion of sacrificial material comprises a substantially flat upper surface at a level which corresponds with the level of the lower surface of the cap membrane layer block. According to preferred embodiments the portion is surrounding the sidewalls of said cavity.

According to embodiments of the third aspect of the present disclosure, the electrical connection between the MEMS device and the bond pad is electrically isolated from the sidewalls of the cavity comprising the MEMS device.

According to embodiments of the third aspect of the present disclosure, the electrical connection between the MEMS device and the bond pad or between the MEMS device and the bond pad membrane layer block does not form part of a sidewall of the cavity.

According to embodiments of the third aspect of the present disclosure, in any of the other embodiments, the electrical connection between the MEMS device in the cavity and the bond pad is located outside the cavity. Preferably the electrical connection does not comprise a metal line located within the cavity. Preferably the MEMS device is electrically contacted via a buried metal layer underneath the cavity.

Features and embodiments for the first, second, and third aspects of the present disclosure, corresponding to features and embodiments of one or more of the other aspects of the present disclosure, are similarly considered to be within the scope of the present disclosure, as will be recognised by the skilled person.

### BRIEF DESCRIPTION OF THE DRAWINGS

The accompanying drawings are used to illustrate embodiments of the present disclosure.

FIGS. 1 to 30 illustrate a semiconductor manufacturing process flow according to a preferred embodiment of the present disclosure.

### DETAILED DESCRIPTION

The above and other advantageous features and objects of the disclosure will become more apparent and the disclosure will be better understood from the following detailed description when read in conjunction with the respective drawings.

The description of aspects of the present disclosure is performed by means of particular embodiments and with reference to certain drawings but the disclosure is not limited thereto. Depicted figures are only exemplary in nature and should not be considered as limiting. E.g. certain elements or features may be shown out of proportion or out of scale with respect to other elements.

In the description of certain embodiments according to the present disclosure, various features are sometimes grouped together in a single embodiment, figure, or description thereof for the purpose of aiding in the understanding of one or more of the various inventive aspects. This is not to be interpreted as if all features of the group are necessarily present to solve a particular problem. Inventive aspects may lie in less than all features of such a group of features present in the description of a particular embodiment.

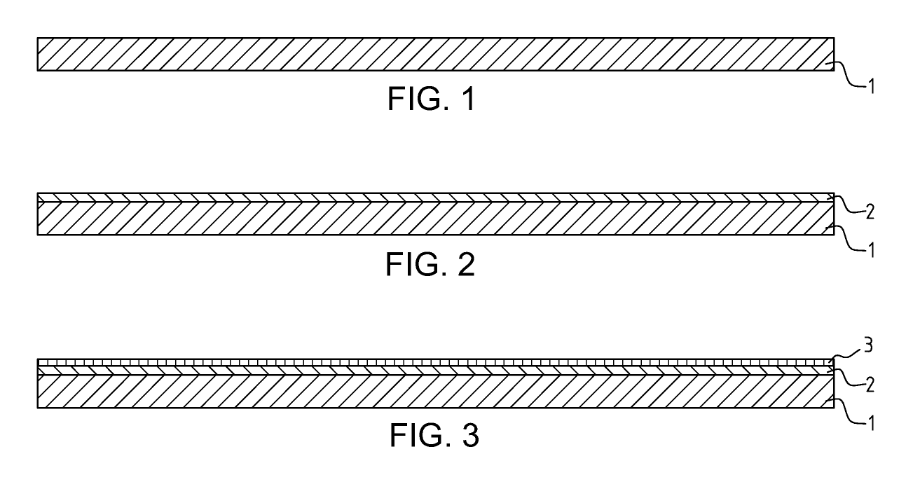

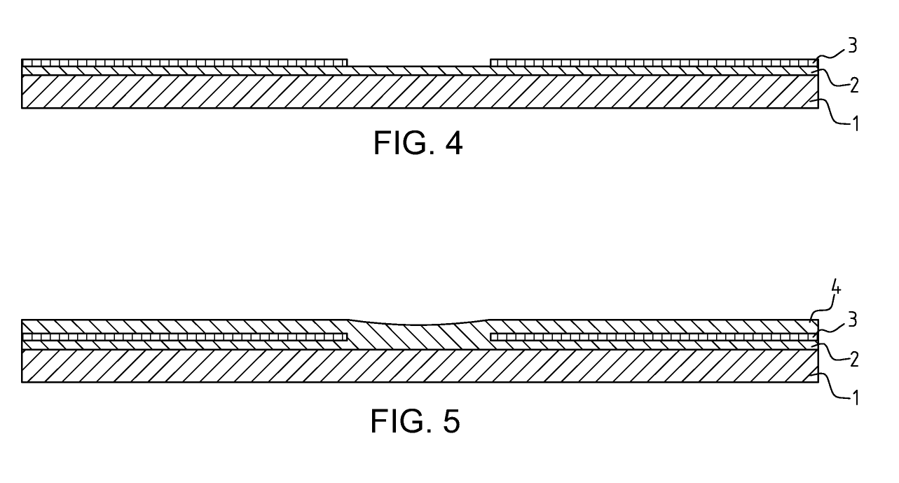

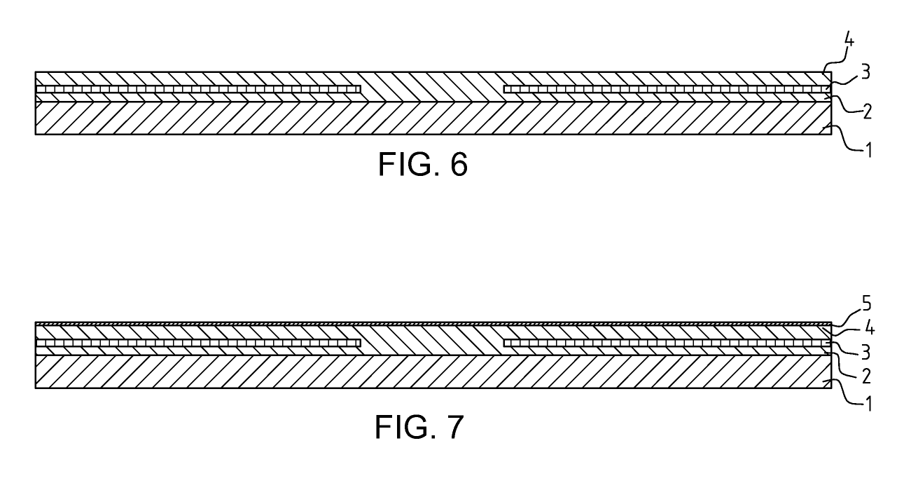

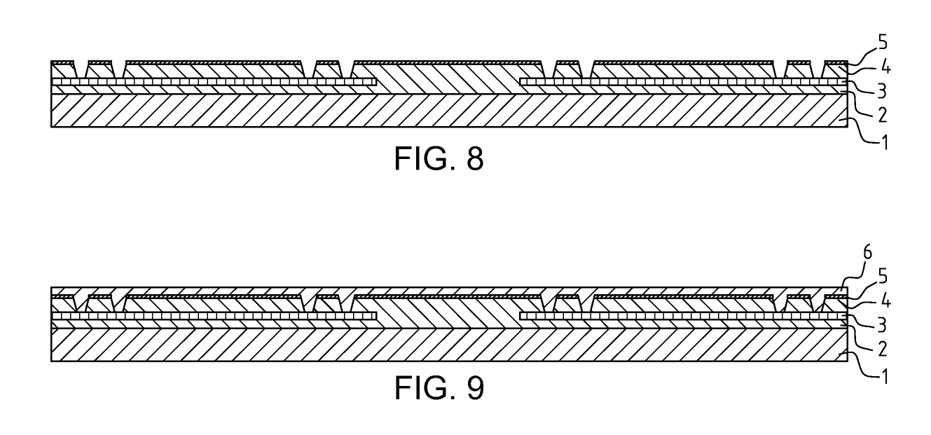

In FIG. 1 a substrate 1, for instance a silicon wafer, is provided. On top of a main surface of the silicon wafer, a silicon oxide (SIO₂) layer 2 with a thickness of e.g. 300 nm, is deposited (FIG. 2). A conductive layer 3 comprising different sub layers is deposited on top of the layer 2. The conductive layer 3 constitutes a buried metal layer. The sub layers can comprise for instance a Ti/AlCu/Ti/TiN stack with a thickness of for instance 20 nm/590 nm/20 nm/45 nm (FIG. 3). Then the conductive layer 3 is patterned as depicted in FIG. 4 by making use of a mask. The conductive layer 3 can be the top metal layer of an interconnect scheme of semiconductor substrate comprising active components such as circuits. The MEMS device is then processed on top of electronic circuitry formed on the substrate. A silicon oxide (SIO₂) layer 4 of about 1500 nm thickness is deposited (see FIG. 5) after which a chemical mechanical polishing (CMP) step is performed in order to flatten the front surface (FIG. 6). The layer 4 is typically sufficiently thick to allow planarizing of the substrate surface. Then a 300 to 400 nm SiC protection layer 5 is deposited (FIG. 7). Openings in layers 5 and 4 are formed using lithographic patterning to form contact holes to the buried conductive layer 3. Using the contact holes an electrical connection (via) can be formed between on the one hand a MEMS device in the cavity and on the other hand the bond pad adjacent to the cavity. The contact etch has been performed with a etch stop on the TiN conductive layer 3, (FIG. 8).

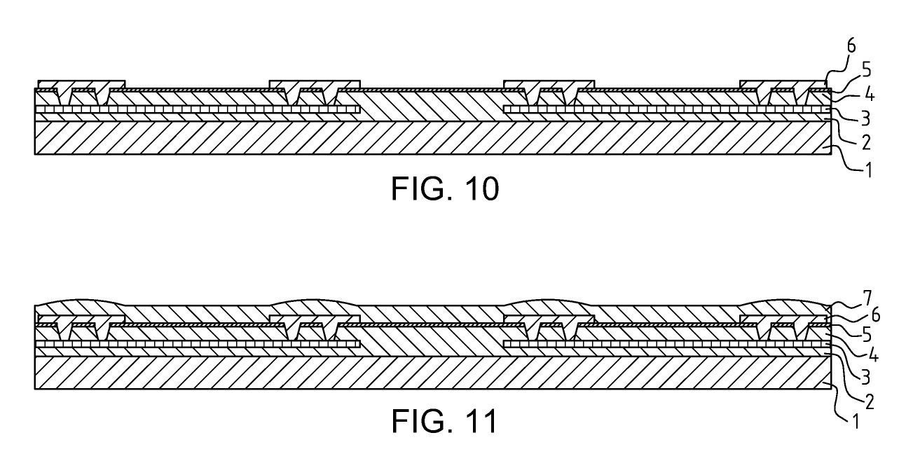

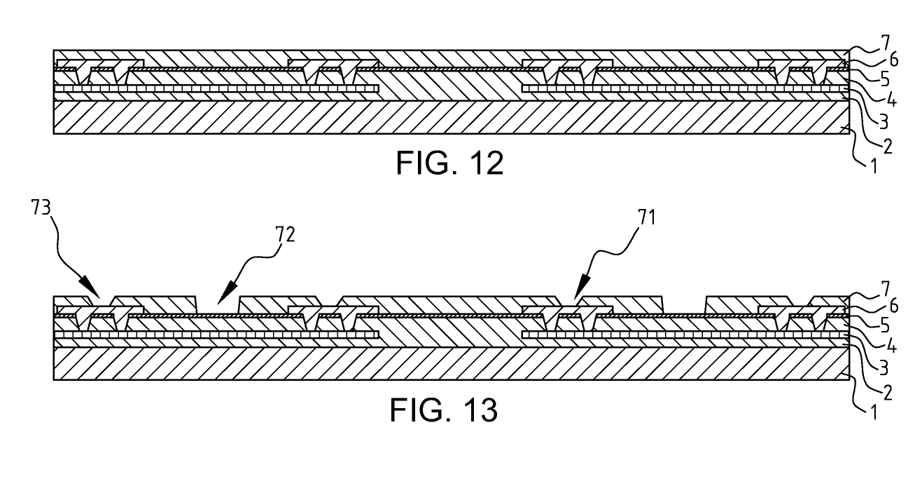

Then a silicon germanium electrode layer 6 is deposited by means of chemical vapour deposition (CVD), for instance having a thickness of 400 nm (FIG. 9), and being connected to the top CMOS electrode conductive layer 3. The silicon germanium layer 6 is patterned into silicon germanium electrodes (FIG. 10), whereupon another sacrificial silicon oxide (SiO₂) layer 7 (thickness typically of about 1 to 3 μm) is deposited (FIG. 11). The sacrificial layer 7 is planarized by applying a chemical mechanical polishing step (FIG. 12), reducing the surface topography for the further lithography steps. A further contact etch is performed by opening the sacrificial oxide 7 to define packaging anchor openings 72 and MEMS feed-through openings 71, 73 (FIG. 13).

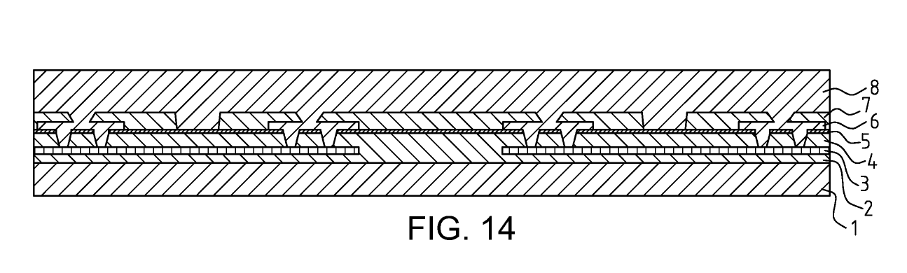

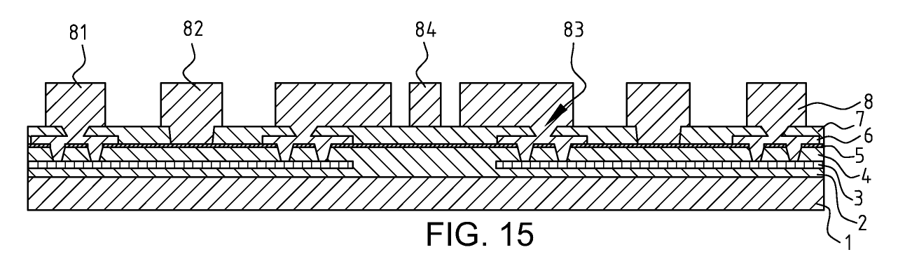

Now, the structural silicon germanium layer 8 is deposited (FIG. 14), typically with a thickness of 1 to 8 μm, optionally together with a 100 nm SiC layer 9 (not depicted). The structural layer is used to form the MEMS device. Then the structural silicon germanium layer 8 (and optionally the SiC layer) is patterned to form the MEMS device 84, part of the packaging anchors 82 and part of the electrical connection 83 between the buried metal layer 3 and the bond pad (FIG. 15).

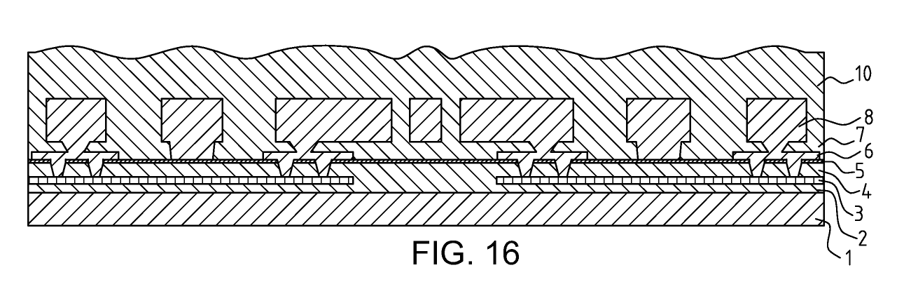

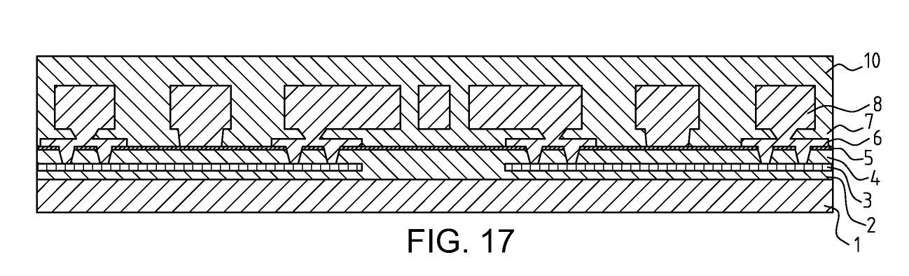

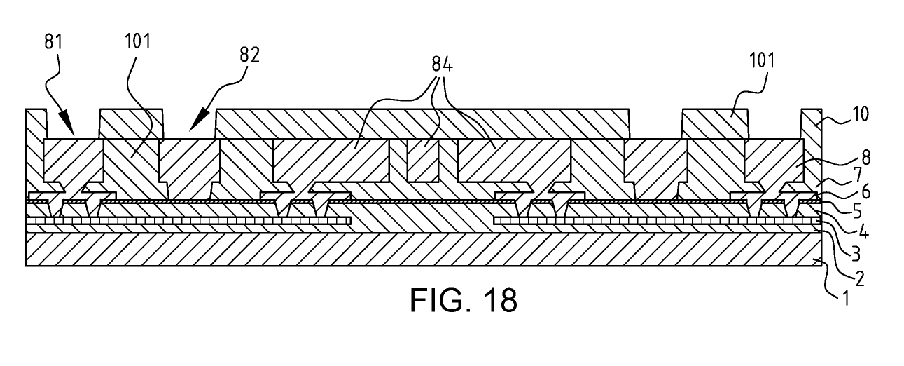

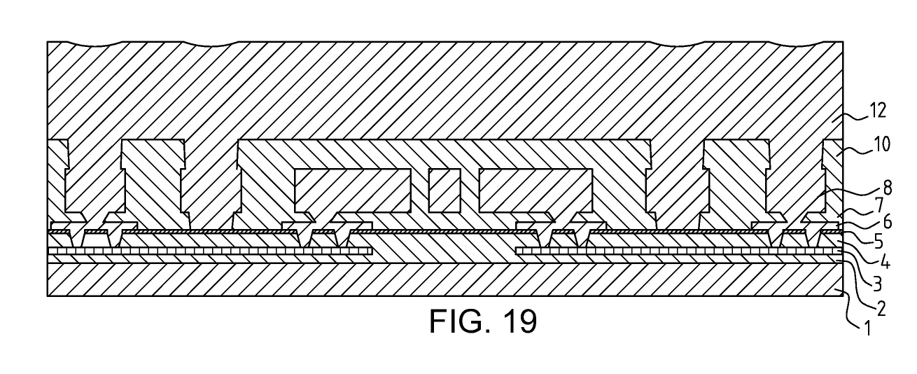

Then, the structure is covered by depositing a silicon oxide layer 10 filling the gaps within the structural layer (FIG. 16). A chemical mechanical polishing (CMP) process is applied from the front main surface on the oxide filling layer 10 (FIG. 17) in order to reduce the topography of the front surface, and thereby define the gap between the structural silicon germanium layer 8 and a silicon germanium membrane layer 12 which is to be deposited. Optionally, the CMP process can be applied up until the level of the SiC layer 9 (CMP stopping layer), if present. In the latter case, another silicon oxide (SIO₂) layer 11 (not shown) is deposited, thereby defining a gap between the structural silicon germanium layer and the silicon germanium membrane layer which will be deposited later. Now, the membrane contact etch is performed in the oxide layer 10 (FIG. 18), to form the anchors 82 of the capping layer and part of the electric connection 81 to the bond pad. Note that remaining portions 101 of the sacrificial layer are present, which can support the electrical connection 81 and the package sidewall or cavity sidewall. The remaining portion has a substantially flat upper surface because of the previous processing.

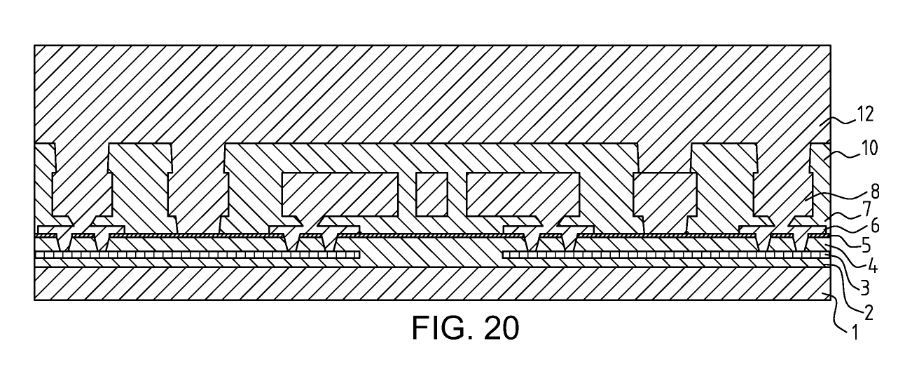

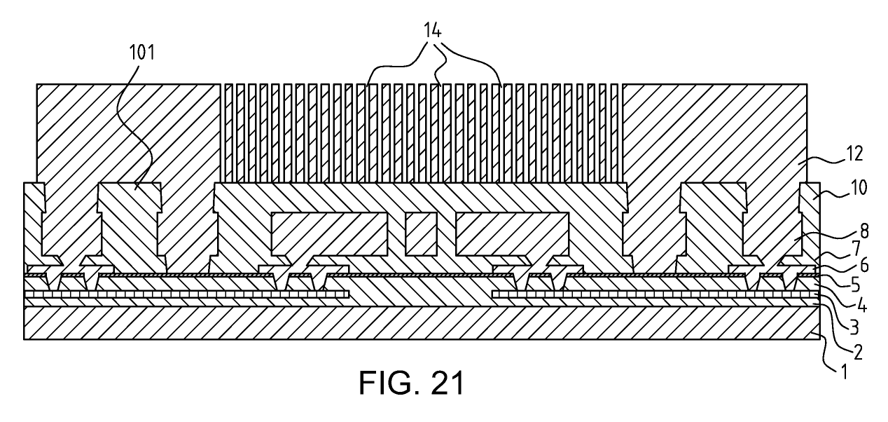

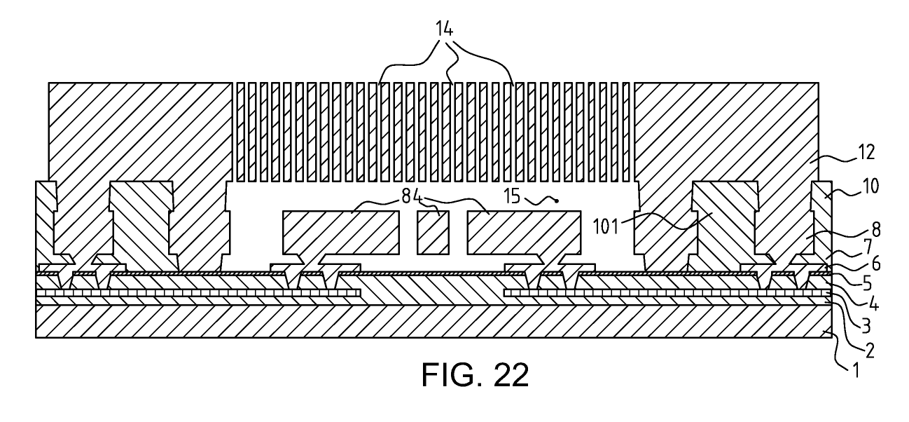

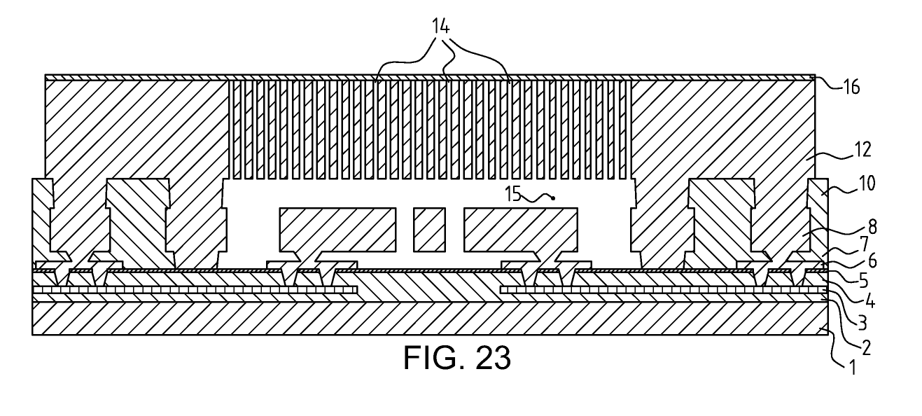

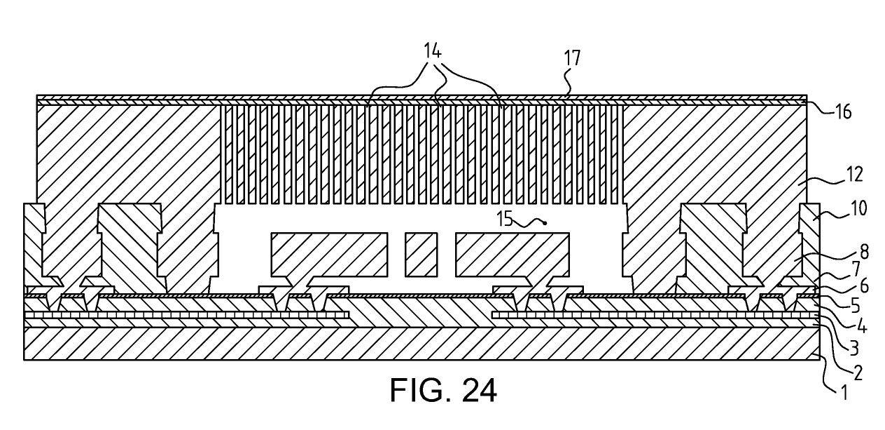

Then the polycrystalline silicon germanium membrane 12 deposition is performed (FIG. 19) (typically having a thickness of 4-10 μm), the front surface of which is optionally planarized by applying a CMP step (FIG. 20), resulting in a substantially flat silicon germanium membrane 12. Note that the level of the substantially flat upper surface of the remaining portion of sacrificial material 101 corresponds to the level of the lower surface the membrane layer 12. Now etch hole definition is performed to define the release holes 14 which will be used for removing the sacrificial material 10 under the membrane layer 12 (FIG. 21). Now the release of the membrane layer 12 and of the functional silicon germanium layer within the formed cavity can be performed by using an etching agent, for instance HF in the gas phase, which is passed through the openings or release holes 14 in the membrane layer 12, in order to remove the material of the sacrificial layers 10 (optionally 11), 7, thereby creating cavity or gap 15 below the membrane layer 12 (FIG. 22), the cavity 15 comprising the MEMS device. It should be noted that at this time in the process sequence, the portion 101 of the layers of sacrificial material 10 (optionally 11), 7 next or adjacent to the cavity 15 is not removed. This improves the strength of the intermediate and/or final device.

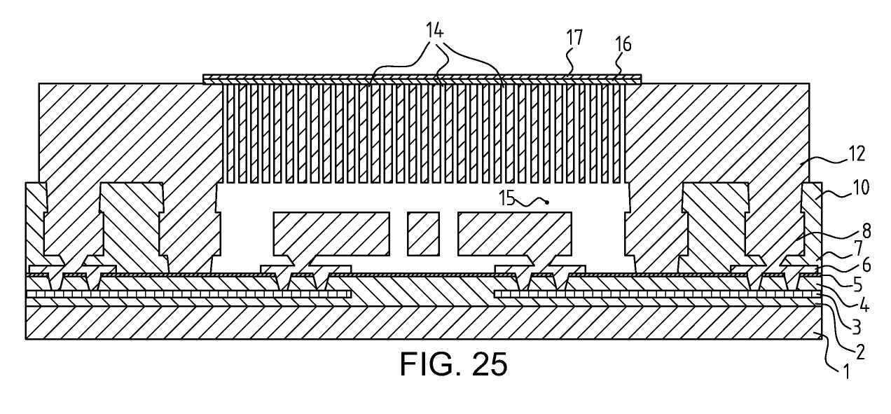

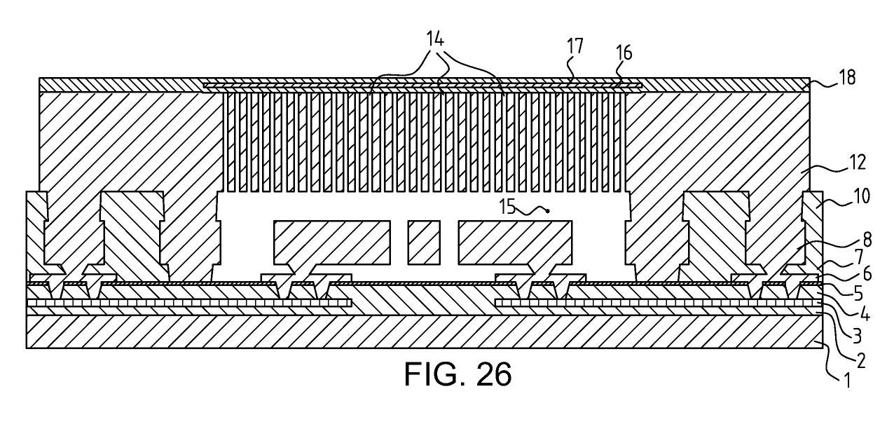

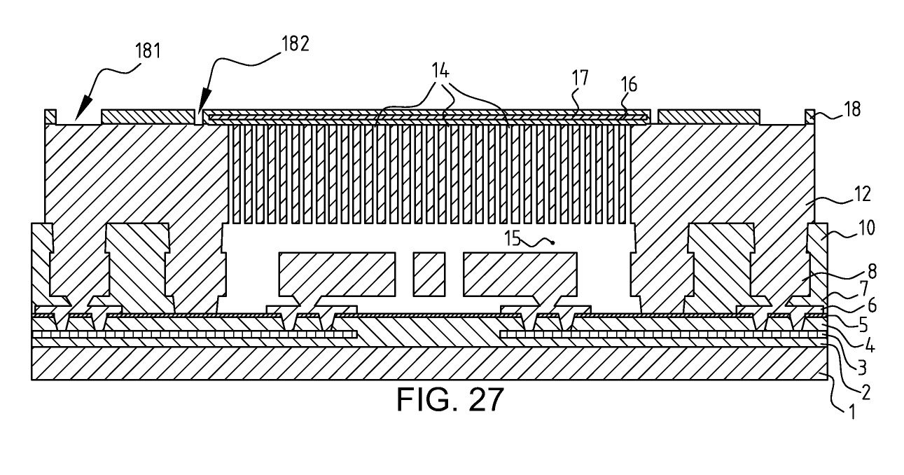

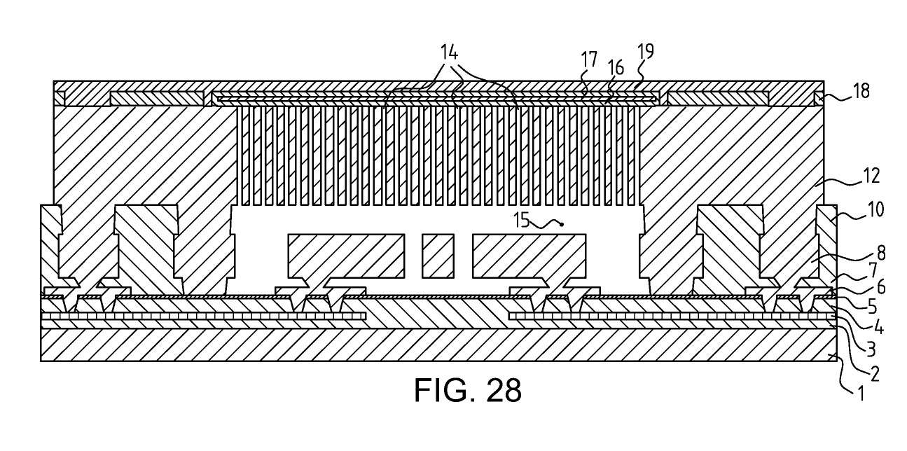

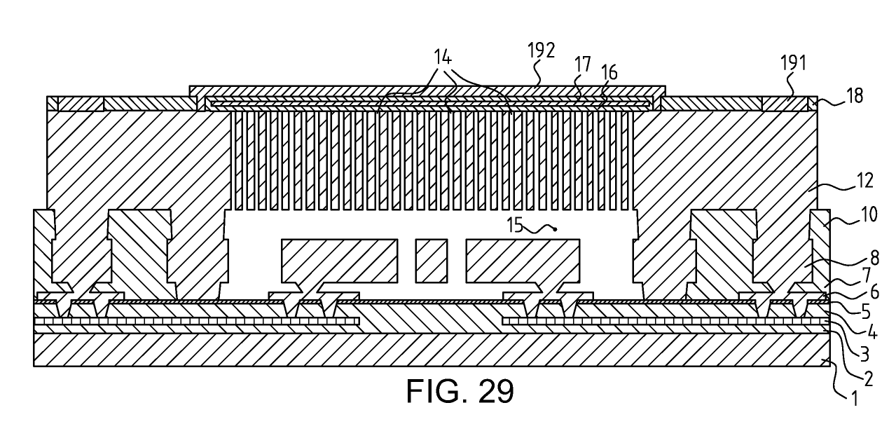

Next the openings or release holes 14 in the membrane layer can be sealed off by state of the art techniques. One of the possible techniques is illustrated below. A sealing layer of silicon oxide 16 is deposited on the front surface of the intermediate device on top of the membrane layer 12 in order to at least partially reduce the width of the openings, or to completely close off the openings (FIG. 23). Later a second sealing layer, for instance an aluminium layer 17, can be deposited (and optionally reflowed) (FIG. 24). The first and second sealing layers, for instance the silicon oxide layer 16 and reflowed aluminium layer 17, thereby provide a sealing layer which hermetically seals the openings 14 in the membrane 12 and thus the cavity 15. The sealing layers 16, 17 are further patterned to only remain at the location of the cavity 15 (FIG. 25), whereupon a further silicon oxide layer 18 is deposited (FIG. 26), acting as an electrical isolation layer surrounding the reflowed aluminium layer 17. The silicon oxide layer or isolation layer 18 is now opened at the locations of the bond pads (FIG. 27), whereupon the bond pad layer 19 deposition is performed (FIG. 28). The bond pad layer 19 can also overlay the cavity 15 thereby improving the hermetic sealing of the cavity 15. As shown in FIG. 27, an additional opening 182 can be formed in the layer 18 adjacent to the patterned sealing layer 16. When depositing the bond layer 19 also the opening 182 is filled with the bond layer material, thereby also sealing off the sidewall of the sealing layer stack 16, 17.

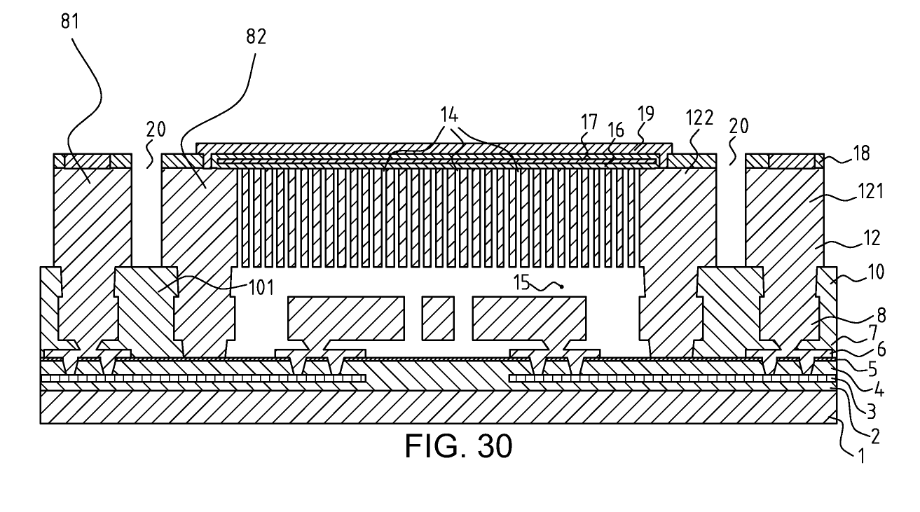

The bond pad layer 19 may comprise aluminium or any material known to be suitable to the skilled person. It may be, for instance, a 900 nm thick Al layer. The bond pad layer 19 (which can optionally be used as an extra sealing layer) is then patterned (FIG. 29) into the bond pads 191 and, optionally, the additional sealing layer 192 on top of the cavity 15.

In the preceding process steps the surface of the membrane layer 12 only contained the small etch holes 14 for removing the sacrificial layer 10 when creating the cavity 15. In that way subsequent processing is not hampered by the topography of the membrane layer 12. Only a final silicon germanium patterning step is applied in order to pattern the membrane layer 12 into at least two independent membrane layer blocks 122 and 121 by providing trenches 20 according to predetermined patterns (FIG. 30). In this patterning step the zero-level package of the cavity 15 formed by layer 12 is separated from the pillar on which the bond pad is formed and which is part of the electrical connection between the bond pad and a buried metal conductive layer 3. The independent membrane layer blocks preferably correspond to caps covering the cavity 15 and bond pad areas associated with the electrical connection, which thus comprise portions of the membrane layer.

While some embodiments described herein include some but not other features included in other embodiments, combinations of features of different embodiments are meant to be within the scope of the disclosure, and form different embodiments, as would be understood by the skilled person.

While the principles of the disclosure have been set out above in connection with specific embodiments, it is to be clearly understood that the description is merely made by way of example and not as a limitation of the scope of protection which is determined by the appended claims.

1. A method of manufacturing a sealed cavity in a microelectronic device, comprising:
forming a sacrificial layer at least at locations where the cavity is to be provided,
depositing a membrane layer on top of the sacrificial layer,
patterning the membrane layer to the level of the sacrificial layer in at least two separate membrane layer blocks,
removing the sacrificial layer through the membrane layer, and
sealing the cavity by sealing the membrane layer,
wherein the patterning the membrane layer is performed after removal of the sacrificial layer.

2. The method according to claim 1, wherein the patterning the membrane layer is performed after sealing of the membrane layer via deposition of a sealing layer.

3. The method according to claim 1, further comprising forming a bond pad on the membrane layer, such that an electrical connection is created between the bond pad and the membrane layer at a location laterally adjacent to the cavity.

4. The method according to claim 1, wherein patterning the membrane layer comprises forming a cap membrane layer block positioned substantially above the cavity.

5. The method according to claim 1, wherein patterning the membrane layer comprises forming a bond pad membrane layer block positioned adjacent to the cavity and separate from a membrane layer block in contact with the cavity.

6. The method according to any claim 1, performed over a substrate comprising at least one buried metal layer, the method further comprising manufacturing at least one MEMS device within the cavity and providing an electrical connection for the MEMS device to the buried metal layer.

7. The method according to claim 6, wherein the manufacturing of at least one MEMS device comprises the formation of a structural MEMS layer, at least a first portion of which is comprised in the MEMS device and at least a second portion of which is comprised in the electrical connection.

8. The method according to claims 7, wherein the patterning of the membrane layer in at least two separate membrane layer blocks comprises isolating the electrical connection from the sidewall of the cavity.

9. The method according to claim 1, further comprising forming at least one hole in the membrane at a location substantially above the cavity, for removing at least part of the sacrificial layer.

10. The method according to claim 9, further comprising forming a plurality of holes in the membrane at locations substantially above the cavity, for removing at least part of the sacrificial layer.

11. The method according to claim 10, further comprising, after removing the part of the sacrificial layer through the plurality of holes, forming a sealing layer over the plurality of holes to seal the cavity.

12. The method according to claim 11, wherein the sealing layer comprises a layer of silicon oxide.

13. The method according to claim 12, wherein the sealing layer further comprises a layer of aluminum formed over the layer of silicon oxide.

14. A microelectronic device comprising a cavity, a membrane layer above the cavity and closing off the cavity, the membrane layer being adapted for allowing the removal of a sacrificial material within the cavity through the membrane layer, wherein the membrane layer is a single piece layer.

15. The microelectronic device according to claim 14, further comprising at least one etch hole in the membrane layer communicating with the cavity to facilitate removal of the sacrificial material.

16. The microelectronic device according to claim 15, further comprising packaging anchors defining the sidewalls of the cavity, and comprising at least a support structure of sacrificial material at locations outside the cavity, the support structure being formed by a portion of a sacrificial material layer used for temporarily filling the cavity with sacrificial material prior to a second portion of the sacrificial material layer being etched away to form the cavity.

17. The microelectronic device according to claim 16, wherein the support structure comprises a substantially flat upper surface at a level which corresponds with the level of a lower surface of the membrane layer.

18. The microelectronic device according to claim 16, wherein the support structure surrounds and joins the packaging anchors outside the cavity.

19. A microelectronic device comprising a sealed cavity delimited by a substrate, sidewalls of the cavity, and a cap membrane layer block positioned above the cavity, wherein at least a support structure is present at locations surrounding the cavity, the support structure being formed by a portion of a sacrificial material layer used for temporarily filling the cavity prior to a second portion of the sacrificial material layer being etched away to form the cavity.
